(19) United States
(12) Patent Application Publication
(10) Pub. No.: US 2025/0336697 A1
(43) Pub. Date: Oct. 30, 2025

(54) SUBSTRATE PROCESSING APPARATUS

(71) Applicant: SAMSUNG ELECTRONICS CO., LTD., Suwon-si (KR)

(72) Inventors: Seungyun Jung, Suwon-si (KR); Seokmin Wi, Suwon-si (KR); Euiseok Kum, Suwon-si (KR); Sang Hoon Kim, Suwon-si (KR)

(73) Assignee: SAMSUNG ELECTRONICS CO., LTD., Suwon-si (KR)

(21) Appl. No.: 18/890,273

(22) Filed: Sep. 19, 2024

(30) Foreign Application Priority Data
Apr. 30, 2024 (KR) 10-2024-0057954

(51) Int. Cl. H01L 21/67; G05B 19/4099; H01L 21/683

(52) U.S. Cl. CPC H01L 21/67248; G05B 19/4099; H01L 21/67109; G05B 2219/45031; H01L 21/6831

(57) ABSTRACT

A substrate processing apparatus may be provided and include: a heater configured to adjust a temperature of a periphery of a wafer substrate; a temperature sensor configured to measure the temperature of the periphery of the wafer substrate; and a controller configured to generate a control input based on a target temperature and based on a measured temperature obtained from the temperature sensor, and transmit the control input to the heater. The controller may be further configured to: calculate a first temperature based on the control input and the measured temperature by removing a time delay of the heater from the measured temperature; estimate a state variable and a disturbance of the heater based on the first temperature and the control input; and generate the control input to be transmitted to the heater based on the target temperature, the state variable, and the disturbance.

### CROSS-REFERENCE TO RELATED APPLICATION

This application claims priority to Korean Patent Application No. 10-2024-0057954, filed in the Korean Intellectual Property Office on Apr. 30, 2024, the entire contents of which are hereby incorporated by reference.

### BACKGROUND

### 1. Field

Embodiments of the present disclosure relate to a substrate processing apparatus.

### 2. Description of Related Art

In a semiconductor manufacturing process, temperature of a wafer processed in a semiconductor processing apparatus such as a plasma processing apparatus may affect the processing result. Therefore, in order to ensure an optimal processing result, it is necessary to properly control temperature in the semiconductor processing apparatus.

For example, temperature of a substrate supporting device such as an electrostatic chuck (ESC) inside a plasma processing apparatus may be controlled with a proportional integral derivative (PID) control method or a model based control method, based on a target temperature (set temperature) and a measured temperature of the electro static chuck (ESC) received from a temperature sensor. The PID control method can control the gain of a controller through repeated experiments without requiring expert knowledge of a system or algorithm to be controlled, and obtain a certain level of temperature control performance. However, the PID control method has a problem in that there is a trade-off relationship between transient response and convergence time.

Meanwhile, the model-based control method is a method of designing a controller by using mathematical model information of a system to be controlled, and this method can design control gain by using a pre-secured system model and obtain higher performance than the PID control method. However, with the model-based control method, it may be difficult to obtain an accurate mathematical model of the system to be controlled, and explaining the controller based on an inaccurate model can result in degraded control performance.

### SUMMARY

In order to solve one or more problems (e.g., the problems described above and/or other problems not explicitly described herein), embodiments of the present disclosure provide a substrate processing apparatus which provides improved temperature control performance.

In order to solve one or more problems (e.g., the problems described above and/or other problems not explicitly described herein), embodiments of the present disclosure provide a substrate processing apparatus capable of improved temperature control without being limited to a model of a system to be controlled.

According to some embodiments of the present disclosure, a substrate processing apparatus is provided and includes: a heater configured to adjust a temperature of a periphery of a wafer substrate; a temperature sensor configured to measure the temperature of the periphery of the wafer substrate; and a controller configured to generate a control input based on a target temperature and based on a measured temperature obtained from the temperature sensor, and transmit the control input to the heater, wherein the controller is further configured to: calculate a first temperature based on the control input and the measured temperature by removing a time delay of the heater from the measured temperature; estimate a state variable and a disturbance of the heater based on the first temperature and the control input; and generate the control input to be transmitted to the heater based on the target temperature, the state variable, and the disturbance.

According to some embodiments of the present disclosure, a substrate processing apparatus is provided and includes: an electro static chuck configured to support a wafer substrate; a heater configured to heat at least one from among the electro static chuck and the wafer substrate; a temperature sensor configured to measure a temperature of the wafer substrate; and a controller configured to generate a control input based on a target temperature and based on a measured temperature obtained from the temperature sensor, and transmit the control input to the heater, wherein the controller includes: a Smith predictor configured to calculate a first temperature based on the control input and the measured temperature by removing a time delay of the heater from the measured temperature; an extended state observer configured to estimate, based on the first temperature and the control input, a second temperature of the heater, a differentiation of the second temperature, and a disturbance; and a compensation controller configured to generate the control input to be transmitted to the heater based on the target temperature, the second temperature, the differentiation of the second temperature, and the disturbance.

According to some embodiments of the present disclosure, a substrate processing apparatus is provided and includes: an electro static chuck configured to support a wafer substrate; a heater configured to heat at least one from among the electro static chuck and the wafer substrate; a temperature sensor configured to measure a temperature of the wafer substrate, wherein the temperature sensor is under the wafer substrate; and a controller configured to generate a control input based on a target temperature and based on a measured temperature obtained from the temperature sensor, and transmit the control input to the heater, wherein the controller includes: a Smith predictor configured to calculate a first temperature based on the control input and the measured temperature by removing a time delay of the heater from the measured temperature; an extended state observer configured to estimate, based on the first temperature and the control input, a second temperature of the heater, a differentiation of the second temperature, and a disturbance; a feedback controller configured to calculate a feedback compensation value based on the target temperature, the second temperature, and the differentiation of the second temperature; and a feedforward controller configured to calculate a feedforward compensation value based on the disturbance.

According to some embodiments of the present disclosure, the temperature control performance of a substrate processing apparatus can be improved and, thus, the stability of the substrate processing apparatus can be improved.

According to some embodiments of the present disclosure, overshoot or undershoot in the transient response section generated during temperature control in a semiconductor processing apparatus equipped with the related PID controller can be substantially removed and, accordingly, generation of foreign substances and plasma instability in the semiconductor processing apparatus due to temperature overshoot can be reduced.

According to some embodiments of the present disclosure, overshoot that may occur during temperature control in a semiconductor processing apparatus can be reduced and, at the same time, stabilization time until arriving at the target temperature can be shortened. Accordingly, the problem of the related PID control method, that is, the trade-off between the transient response characteristics and the rate of convergence with respect to the target temperature value can be solved.

According to some embodiments of the present disclosure, greatly enhanced temperature control performance can be obtained without using different models for various target temperatures or various temperature change sections for temperature control set in a semiconductor processing apparatus.

### BRIEF DESCRIPTION OF DRAWINGS

FIG. 1 is a conceptual diagram illustrating a configuration of a substrate processing apparatus capable of performing a method for controlling temperature according to some example embodiments of the present disclosure.

FIG. 2 is a cross-sectional diagram illustrating a configuration of a substrate processing apparatus according to some example embodiments of the present disclosure.

FIG. 3 is a block diagram of a temperature control system of a substrate processing apparatus according to some example embodiments of the present disclosure.

FIGS. 4 and 5 are block diagrams illustrating a configuration of a control unit of the substrate processing apparatus according to some example embodiments of the present disclosure.

FIG. 6 is a block diagram illustrating a configuration of a Smith predictor of the control unit.

FIG. 7 is a block diagram illustrating a configuration of an extended state observer of the control unit.

FIG. 8 is a block diagram illustrating a configuration of a compensation controller of the control unit.

FIGS. 9 to 11 are graphs illustrating temperature change of the substrate processing apparatus according to some example embodiments of the present disclosure.

FIG. 12 is a flowchart provided to explain a method for controlling temperature of a substrate processing apparatus according to some example embodiments of the present disclosure.

FIG. 13 is a block diagram illustrating a configuration of a computing device in which the control unit is implemented according to some example embodiments of the present disclosure.

### DETAILED DESCRIPTION

Hereinafter, a method for controlling temperature of a substrate processing apparatus according to some non-limiting example embodiments of the present disclosure will be described in detail with reference to the drawings.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

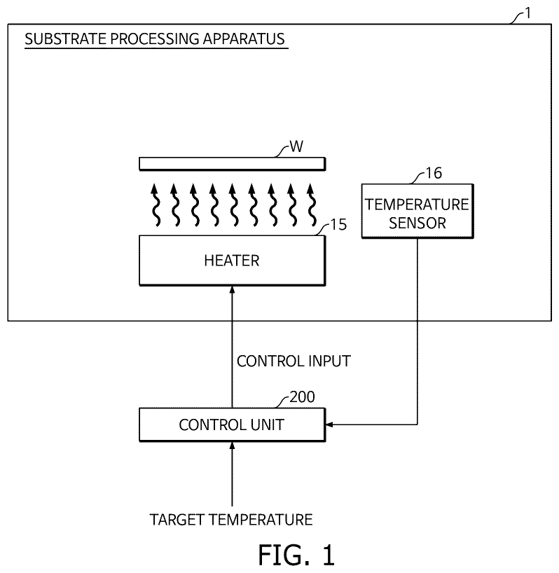

FIG. 1 is a conceptual diagram illustrating a configuration of a substrate processing apparatus capable of performing a method for controlling temperature according to some example embodiments of the present disclosure.

Referring to FIG. 1, a substrate processing apparatus 1 according to some example embodiments of the present disclosure may include a heater 15 that heats a substrate W or a periphery of the substrate W, a temperature sensor 16 that measures the temperature of the substrate W or the periphery of the substrate W, and a control unit 200 (e.g., a controller) that controls the heater 15 based on the measured temperature received from the temperature sensor 16. Although FIG. 1 illustrates that the control unit 200 is placed outside the substrate processing apparatus 1, embodiments of the present disclosure are not limited thereto, and the control unit 200 may be installed inside the substrate processing apparatus 1 or installed in an external computing device capable of communicating with the substrate processing apparatus 1.

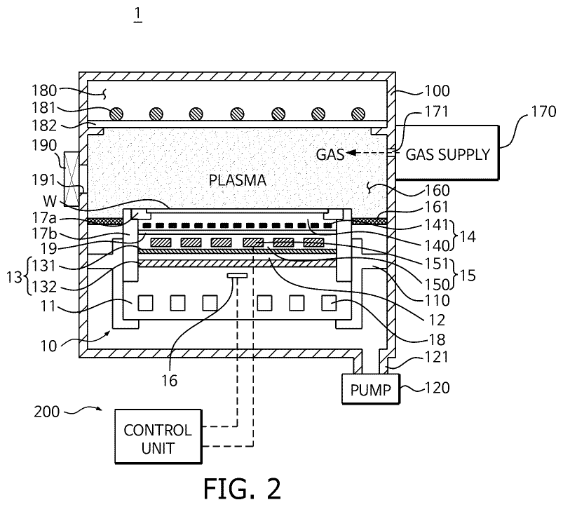

According to embodiments, the substrate processing apparatus 1 may further include a substrate support part (e.g., an electro static chuck 10 in FIG. 2) that fixedly supports the wafer substrate W. In addition, it is illustrated that the substrate processing apparatus 1 includes only the heater 15, but embodiments of the present disclosure are not limited thereto, and the substrate processing apparatus 1 may further include a cooler that cools the wafer substrate W or the periphery of the wafer substrate W.

The heater 15 may adjust the temperature of the wafer substrate W by generating heat to the wafer substrate W or the periphery of the wafer substrate W. For example, the heater 15 may adjust the temperature of the wafer substrate W by heating a substrate support part that supports the wafer substrate W. That is, the heater 15 may adjust the temperature of the wafer substrate W by adjusting the temperature of the substrate support part.

The temperature sensor 16 may measure the temperature of the wafer substrate W or the periphery of the wafer substrate W. Alternatively, the temperature sensor 16 may measure the temperature of the substrate support part (or a periphery thereof) that supports the wafer substrate W. In addition, the temperature sensor 16 may transmit the measured temperature to the control unit 200.

The control unit 200 may control the heater 15 to adjust an amount of heat generated by the heater 15, and thereby adjust the temperature of the wafer substrate W or the periphery of the substrate W. The control unit 200 may generate a control input based on a received target temperature and the measured temperature obtained from the temperature sensor 16. The control unit 200 may transmit the generated control input to the heater 15. The heater 15 may adjust the temperature of the periphery of the wafer substrate W based on the control input received from the control unit 200.

If the target temperature is higher than the temperature obtained from the temperature sensor 16, the control unit 200 may control the heater 15 to generate heat. Conversely, if the target temperature is lower than the temperature obtained from the temperature sensor 16, the control unit 200 may perform control so as to stop operation of the heater 15 or reduce the amount of heat generated by the heater 15. Alternatively, if the target temperature is the same as the temperature obtained from the temperature sensor 16, the control unit 200 may control the heater 15 to adjust the amount of heat so as to maintain the current temperature.

Additionally, the control unit 200 may control a cooler 18 (see FIG. 2) to cool down the temperature of the wafer substrate W or the periphery of the substrate W. The control unit 200 may generate a control input based on a received target temperature and the measured temperature obtained from the temperature sensor 16. The control unit 200 may transmit the generated control input to the cooler 18. The cooler 18 may adjust the temperature of the periphery of the wafer substrate W based on the control input received from the control unit 200.

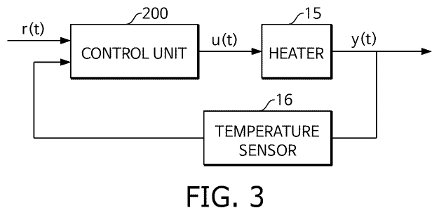

Based on the previously generated control input and the measured temperature obtained from the temperature sensor 16, the control unit 200 may calculate a temperature by removing a time delay of the heater 15 and/or the cooler 18 from the measured temperature, and estimate a state variable and disturbance of the heater 15 and/or the cooler based on the calculated temperature and the control input. In addition, the control unit 200 may generate a control input to be transmitted to the heater 15 and/or the cooler 18 based on the target temperature, the estimated state variable, and the disturbance. A method for controlling the heater 15 or the cooler by the control unit 200 will be described below with reference to FIGS. 3 to 8.

FIG. 2 is a cross-sectional diagram illustrating a configuration of a substrate processing apparatus according to some example embodiments of the present disclosure.

Referring to FIG. 2, the substrate processing apparatus 1 according to some example embodiments of the present disclosure may include an electro static chuck 10 installed below a chamber 100 to support the wafer substrate W, an antenna chamber 180 including a high frequency antenna 181 installed above the chamber 100 to generate plasma, a gas supply 170 installed on a sidewall of the chamber 100 to supply processing gas such as etching gas to the chamber 100, a vacuum pump 120 installed below the chamber 100 to exhaust gas in the chamber 100 to an outside, and the control unit 200 that generates a control input for the temperature control by the heater 15 or the cooler 18 installed inside the electro static chuck 10.

The substrate processing apparatus 1 may be an apparatus provided to etch a film to be etched on a substrate such as the wafer substrate W disposed in a capacitive coupled plasma (CCP) chamber. Meanwhile, the plasma generated by the substrate processing apparatus is not limited to the capacitively coupled plasma, and may be, for example, an inductively coupled plasma (ICP) or a microwave-type plasma.

In addition, the plasma processing apparatus is not necessarily limited to an etching device, and may be, for example, a deposition device, a cleaning device, etc. The wafer substrate W may include a semiconductor substrate, a glass substrate, etc.

The electro static chuck 10 may be disposed on a lower center of the chamber 100. In addition, the electro static chuck 10 may be supported by a support part 110 fixed to an inner sidewall of the chamber 100. A baffle plate 161 may be disposed between the electro static chuck 10 and the inner sidewall of the chamber 100.

The electro static chuck 10 may keep the wafer substrate W disposed thereon with electrostatic adsorption force. To this end, the electro static chuck 10 may include an electrostatic module 14 that generates the electrostatic force to fix the wafer substrate W. The electrostatic module 14 may include an electrostatic dielectric layer 140 on (e.g., in) which an adsorption electrode 141 is mounted, and the wafer substrate W may be disposed on the electrostatic dielectric layer 140. The electrostatic module 14 may further include the adsorption electrode 141 mounted on (e.g., in) the electrostatic dielectric layer 140. The adsorption electrode 141 may be referred to as a clamp electrode. The adsorption electrode 141 may generate, with DC voltage, the electrostatic force between the adsorption electrode 141 and the wafer substrate W. By the electrostatic force, the wafer substrate W may be adsorbed onto the electrostatic dielectric layer 140.

The adsorption electrode 141 may be a conductor. For example, the adsorption electrode 141 may include a metal such as tungsten (W), copper (Cu), nickel (Ni), molybdenum (Mo), nickel-chromium alloy (Ni—Cr alloy), nickel-aluminum alloy (Ni—Al alloy) etc., or a conductive ceramic such as tungsten carbide (WC), molybdenum carbide (MoC), titanium nitride (TiN) etc. Further, the electrostatic dielectric layer 140 may be formed of a dielectric material such as ceramic or resin. The electrostatic dielectric layer 140 may have a shape of a circle or a disk.

The electro static chuck 10 may include the heater 15 provided to control temperature of the electro static chuck 10. The heater 15 may include a heater dielectric layer 150 and a heater electrode 145 mounted on (e.g., in) the heater dielectric layer 150. The heater dielectric layer 150 may be formed of a dielectric material such as ceramic or resin. The heater dielectric layer 150 may have a shape of a circle or a disk.

The substrate processing apparatus 1 may further include the temperature sensor 16. The temperature sensor 16 may be positioned inside a base 11 of the electro static chuck 10. However, the position of the temperature sensor 16 is not limited to the above. The temperature sensor 16 may be positioned outside the base 11. The temperature sensor 16 may transmit the measured temperature of the base 11 to the control unit 200. The temperature sensor 16 may directly measure the temperature of the wafer substrate W. Alternatively, the temperature of the electro static chuck 10 or the temperature of the wafer substrate W may be estimated from the temperature measured by the temperature sensor 16. The temperature sensor 16 may transmit the measured temperature or the estimated temperature of the wafer substrate W to the control unit 200.

The electro static chuck 10 may include a heat transfer layer 19 provided between the heater dielectric layer 150 and the electrostatic dielectric layer 140. The heat transfer layer 19 may include a material having a thermal conductivity of about 10 W/m·K or more. For example, the heat transfer layer 19 may include an aluminum nitride (AlN) layer, a boron nitride (BN) layer, a tungsten (W) layer, a molybdenum (Mo) layer, etc. The heat transfer layer 19 may distribute heat generated from the heater electrode 151 more uniformly.

It is desirable to prevent an electrical short from occurring between the adsorption electrode 141 and the heater electrode 151. The electrical resistance between the adsorption electrode 141 and the heater electrode 151 may be about 1 kΩ or more. In other words, the electrostatic dielectric layer 140, the heater dielectric layer 150, and the heat transfer layer 19 may include a material that allows the electrical resistance between the adsorption electrode 141 and the heater electrode 151 to be about 1 kΩ at least.

The electro static chuck 10 may further include the cooler 18 that cools the wafer substrate W. The cooler 18 may be positioned in the base 11. For example, a coolant used in the cooler 18 may include helium gas, water, ethylene glycol, silicone oil, liquid Teflon, and a mixture of water and glycol. The cooler 18 may have a concentric or helical pipe structure around the central axis of the base 11. The cooler 18 may include a coolant pump and a storage. The cooler 18 may be operated to selectively supply the coolant based on a control input transmitted by the control unit 200. The control unit 200 may control the temperature of the electro static chuck 10 or the wafer substrate W by adjusting, through the control input, a flow rate of the coolant supplied to the cooler 18. However, the method for controlling the temperature of the cooler 18 is not limited thereto.

The electro static chuck 10 may include a focus ring 17a extending along a circumference of the wafer substrate W and surrounding the wafer substrate W in a ring shape. The focus ring 17a may be provided to improve wafer processing (e.g., uniformity of plasma etching). The focus ring 17a may include a material having a dielectric constant of 3 or less or a resistivity of 100 Ωcm or less. The focus ring 17a may include quartz, aluminum oxide (Al₂O₃), yttrium oxide (Y₂O₃), silicon (Si), silicon carbide (SiC), carbon (C), silicon oxide (SiO₂), etc. An outer ring 17b shielding an outer wall of the electro static chuck 10 may be further provided. The outer ring 17b may be formed of the same or similar material as the material of the focus ring 17a.

The substrate processing apparatus 1 may include an exhaust pipe 121 provided under the chamber 100, and the exhaust pipe 121 may be connected to the vacuum pump 120. A gate valve 190 that opens and closes an opening 191 for entrance and exit of the wafer substrate W may be provided on the outer wall of the chamber 100.

The substrate processing apparatus 1 may include the antenna chamber 180 disposed above the chamber 100. The antenna chamber 180 may be integrally installed with the chamber 100. The high frequency antenna 181 for generating plasma may be received in the antenna chamber 180. The high frequency antenna 181 may output high frequency power suitable for the plasma generation. Further, a dielectric window 182 may be disposed in the antenna chamber 180, while being spaced apart from the electro static chuck 10.

The gas supply 170 may supply a processing gas such as an etching gas to the chamber 100 through a supply means such as a nozzle or a hole formed on the sidewall of the chamber 100. The etching gas introduced into the chamber 100 may be uniformly diffused in a processing chamber 160 under the dielectric window 182. Magnetic field may be generated around the high frequency antenna 181 by the electrical current flowing through the high frequency antenna 181, and magnetic force line may pass through the dielectric window 182 and through the processing chamber 160. Induced electrical field may be generated by a temporal change of the magnetic field, and electrons accelerated by the induced electrical field may collide with molecules or atoms of the etching gas, and plasma is generated.

Using a plasma generating unit including the gas supply 170 and the antenna chamber 180, plasma ions may be supplied to the wafer substrate W and wafer processing (e.g., etching processing) may be performed in the processing chamber 160.

In order to perform the etching process with the substrate processing apparatus 1, the gate valve 190 may be opened so that the wafer substrate W is loaded (or mounted) on the electro static chuck 10 in the chamber 100. The wafer substrate W may be adsorbed onto the electro static chuck 10 by the electrostatic force generated in the electro static chuck 10.

The electro static chuck 10 may be used in a plasma processing apparatus that processes the wafer substrate W using plasma. In this case, the inside of the chamber 100 where the electro static chuck 10 is installed is in high-temperature environment, and if the wafer substrate W is exposed to high-temperature plasma, the wafer substrate W may be subject to damages such as ion bombardment. It is desirable to adjust the temperature of the wafer substrate W to avoid the damages to the wafer substrate W and to perform uniform plasma processing. Specifically, if the temperature of the electro static chuck 10 rapidly changes, stability problems related to plasma may occur.

Further, if the temperature of the electro static chuck 10 or wafer substrate W changes rapidly, problems may occur such that fine particles may be generated in the chamber 100, causing defects on the wafer substrate W. Since these problems may reduce the yield of semiconductors, it is desirable to prevent the same.

In order to solve the stability problems related to plasma, the control unit 200 may generate a control input for controlling the temperature of the wafer substrate W, and transmit the generated control input to the heater 15 or the cooler 18. However, examples are not limited to the above, and the control unit 200 may control the operation of the electrostatic module 14. The control unit 200 may control the operation of the heater 15 or the cooler 18 based on the temperature of the electro static chuck 10 or temperature of the wafer substrate W detected by the temperature sensor 16.

Based on the previously generated control input and the measured temperature obtained from the temperature sensor 16, the control unit 200 may calculate a temperature by removing a time delay of the heater 15 and/or the cooler 18 from the measured temperature, and estimate the state variable and disturbance of the heater 15 and/or the cooler 18 based on the calculated temperature and the control input. In addition, the control unit 200 may generate a control input to be transmitted to the heater 15 and/or the cooler 18 based on the set temperature, the estimated state variable, and the disturbance. A method for controlling the heater 15 and/or the cooler 18 by the control unit 200 will be described below with reference to FIGS. 3 to 8.

FIG. 3 is a block diagram of a temperature control system of a substrate processing apparatus according to some example embodiments of the present disclosure.

Referring to FIG. 3, the temperature control system of the substrate processing apparatus according to some example embodiments of the present disclosure may include the temperature sensor 16 that measures the temperature of the wafer substrate or a periphery of the wafer substrate, the heater 15 that heats the wafer substrate or a periphery of the wafer substrate, and the control unit 200 provided to control the operation of the heater 15.

The control unit 200 may receive control information. For example, the control unit 200 may receive a target temperature or a set temperature. The control unit 200 may be installed inside or outside the substrate processing apparatus (e.g., the substrate processing apparatus 1, see FIG. 2). If the control unit 200 is installed outside the substrate processing apparatus, a transceiving device, a communication line, etc., for wireless or wired communication between the substrate processing apparatus 1 and the control unit 200 may be installed.

The control unit 200 may receive a set temperature r(t). The control unit 200 may determine the target temperature of the wafer substrate W based on the set temperature r(t) according to the process recipe of the wafer substrate W. Alternatively, the control unit 200 may determine the set temperature r(t) is the target temperature.

The temperature sensor 16 may detect the temperature of the electro static chuck or the wafer substrate. To this end, for example, the temperature sensor 16 may be installed inside or around the electro static chuck installed in the chamber of the substrate processing apparatus. In addition, the temperature sensor 16 may include a chamber temperature sensor to detect an inside temperature of the chamber, a temperature sensor to detect a temperature of gas received in the chamber, or a temperature sensor to detect a temperature of the coolant of the cooler. In the present disclosure, it is assumed that the temperature sensor 16 is a temperature sensor for detecting the temperature of the electro static chuck or the wafer substrate, but the temperature control system of the substrate processing apparatus of example embodiments of the present disclosure may include at least one of the various temperature sensors described above.

A measured temperature y(t) detected by the temperature sensor 16 may be provided to the control unit 200. The control unit 200 may generate a control input u(t) to transmit to the heater 15 based on the input set temperature r(t) and the measured temperature y(t). Based on the previously generated control input and the measured temperature y(t), the control unit 200 may calculate a temperature by removing the time delay of the heater 15 from the measured temperature y(t), and estimate the state variable and disturbance of the heater 15 based on the calculated temperature and the previously generated control input. In addition, the control unit 200 may generate a control input u(t) to transmit to the heater 15 based on the set temperature r(t), the estimated state variable, and disturbance.

The control unit 200 may use (e.g., include) an extended state observer (ESO) that can estimate the state variable and model uncertainty (or disturbance) of the heater 15 to implement the temperature control described above. The extended state observer may estimate the state variable and disturbance of the heater 15 in real time using only the model information that models the heater 15 system with approximate modeling. That is, based on the approximate modeling, the extended state observer treats a difference between the actual heater system and the approximate linear model as disturbance and estimates the same, and provides the estimated disturbance to a compensation controller. The compensation controller may use the estimated disturbance in a feedforward form when the control input is generated. The measured temperature obtained from the temperature sensor 16 and the previously generated control input may be input to the extended state observer. As a result, the extended state observer may estimate the state variable and disturbance of the heater 15 based on the measured temperature and the previously generated control input.

In addition, the control unit 200 may use (e.g., include) the compensation controller that may perform feedback control and feedforward control on temperature based on the state variables and disturbance estimated by the extended state observer. The compensation controller may use the feedback/feedforward control method to generate a control input u(t) to transmit to the heater 15 based on the set temperature r(t) and the state variable, and disturbance estimated by the extended state observer.

According to another example, the control unit 200 may further include a Smith predictor that may estimate the time delay of the heater 15 based on a heater model that models the time delay of the heater 15 with approximate modeling. It is desirable for the control unit 200 to estimate the delay time that may take until there is a temperature change of the heater 15. For example, the heater 15 may have a temperature change to the set temperature only after several seconds elapses since power is applied. The control unit 200 may input the measured temperature y(t) to the Smith predictor to calculate the temperature from which the time delay of the heater 15 is removed.

In this case, in the control unit 200, the temperature from which the time delay of the heater 15 calculated by the Smith predictor is removed may be input to the extended state observer. As a result, the extended state observer may estimate the state variable and disturbance of the heater 15 based on the temperature calculated by the Smith predictor and the previously generated control input. In addition, the compensation controller of the control unit 200 may use the feedback/feedforward control method to generate a control input u(t) to transmit to the heater 15 based on the set temperature r(t), the state variable, and disturbance estimated by the extended state observer.

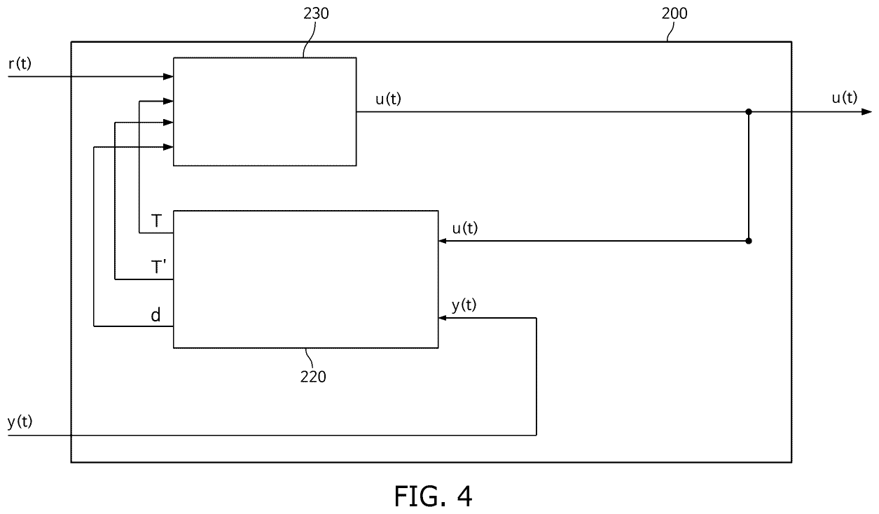

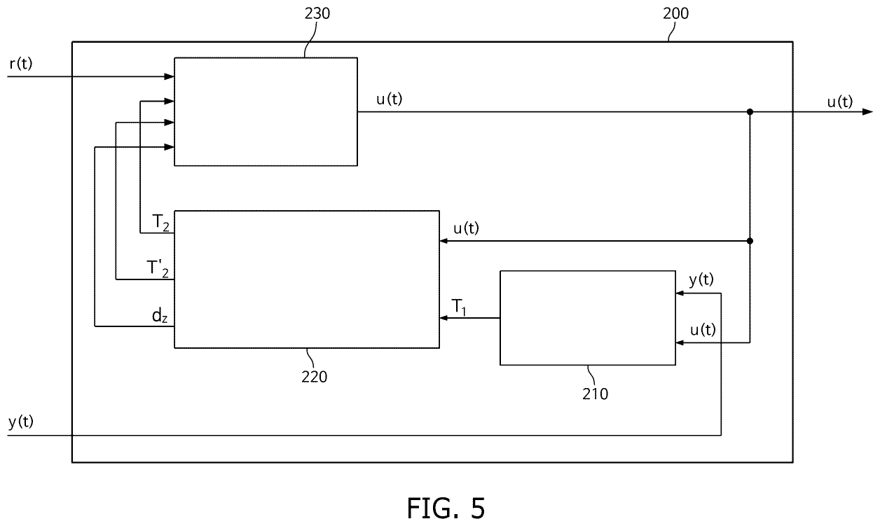

FIGS. 4 and 5 are block diagrams illustrating a configuration of a control unit of the substrate processing apparatus according to some example embodiments of the present disclosure.

Referring to FIG. 4, the control unit 200 may include an extended state observer 220 and a compensation controller 230.

The extended state observer 220 may estimate the state variable and disturbance of the heater 15 based on the measured temperature y(t) obtained from the temperature sensor (e.g., the temperature sensor 16, see FIG. 3) and the control input u(t) of the control unit 200.

The extended state observer 220 may estimate the state variable and disturbance of a mathematical model of the heater 15 system obtained in the form of transfer function. For example, the extended state observer 220 may be designed based on an approximate modeling of the heater 15 system that adjusts the temperature of the electro static chuck (e.g., the electro static chuck 10, see FIG. 2) installed in the semiconductor processing apparatus.

The heater 15 system that adjusts the temperature of the electro static chuck may be approximated by, for example, a secondary transfer function with a time delay, expressed through Laplace transform in the frequency domain(s) as shown in the following Equation 1:

$$G ( s ) = \frac{b}{{s}^{2} + {a}_{1} s + {a}_{2}} {e}^{- cs} \qquad ( Equation 1 )$$

Because the extended state observer 220 is an observer that does not take into account the time delay, the time delay term e^{-cs} of the secondary transfer function can be ignored. Accordingly, the mathematical model of the heater 15 system used by the extended state observer 220 may be described by the following secondary transfer function (Equation 2):

$${G}_{0} ( s ) = \frac{b}{{s}^{2} + {a}_{1} s + {a}_{2}} \qquad ( Equation 2 )$$

In addition, by converting the mathematical model of the heater 15 system into a controllable canonical form and then into a state-space equation, the state of the heater 15 system may be described by the following Equation 3.

$$\dot{\overline{X}} = A \overline{X} + Bu , {y}_{m} = {y}_{o} = C \overline{X} , \qquad ( Equation 3 )$$

$$A = ( \begin{matrix}0 & 1 \\ - {a}_{2} & - {a}_{1}\end{matrix} ) ,$$

$$B = ( \begin{matrix}0 \\ 1\end{matrix} ) ,$$

$$C = ( \begin{matrix}b & 0\end{matrix} ) ,$$

$$\overline{X} = {( \begin{matrix}{x}_{1} & {x}_{2}\end{matrix} )}^{T} ∈ {R}^{2 \times 1}$$

where, yₒ may be a result of a system to be controlled, that is, a measured temperature measured by the temperature sensor 16. Meanwhile, in order to design the extended state observer 220, it is possible to define a new variable yₒ with a differentiation of yₒ and yₒ, and represent A_{z}, B_{z}, and C_{z} as shown below in Equation 4.

$$\overline{z} = {( \begin{matrix}{y}_{o} & {\dot{y}}_{o}\end{matrix} )}^{T} ∈ {R}^{2 \times 1} \qquad ( Equation 4 )$$

$$\dot{\overline{z}} = {A}_{z} \overline{z} + {B}_{z} u = \dot{\overline{z}} = ( \begin{matrix}0 & 1 \\ - {a}_{2} & - {a}_{1}\end{matrix} ) \overline{z} + ( \begin{matrix}0 \\ {b}_{0}\end{matrix} ) u + ( \begin{matrix}0 \\ {d}_{z}\end{matrix} )$$

$${y}_{z} = {C}_{z} \overline{z} = ( \begin{matrix}1 & 0\end{matrix} ) \overline{z}$$

In the above equation, the difference between the actual heater 15 system and the modeled system may be expressed as a model uncertainty or disturbance d_{z}. The time change of disturbance d_{z} may be assumed to be bounded (\dot{d}_{z}=h). With this assumption, it is possible to exclude the abrupt disturbance from the modeled system.

In addition, when defining a mathematical formula of the extended state (z̅ₑₓ) of the heater 15 system in consideration of disturbance dz, it can be described as the following Equation 5 and Equation 6:

$${\overline{z}}_{ex} = {( \begin{matrix}{y}_{o} & {\dot{y}}_{o} & {d}_{z}\end{matrix} )}^{T} , \qquad ( Equation 5 )$$

$${\dot{z}}_{ex} = ( \begin{matrix}0 & 1 & 0 \\ - {a}_{2} & - {a}_{1} & 1 \\ 0 & 0 & 0\end{matrix} ) {\overline{z}}_{ex} + ( \begin{matrix}0 \\ {b}_{0} \\ 0\end{matrix} ) u + ( \begin{matrix}0 \\ 0 \\ 1\end{matrix} ) h = {A}_{z , ex} {\overline{z}}_{ex} + {B}_{z , ex} u + Eh \qquad ( Equation 6 )$$

Finally, the extended state observer 220 may be designed as shown in the following Equation 7, where ŷₒ may be a temperature value estimated by the extended state observer 220. The observer gain matrix L of the extended state observer 220 may be designed to be sufficiently large as follows in Equation 7:

$${\dot{\hat{z}}}_{ex} = {A}_{z , ex} {\hat{z}}_{ex} + {B}_{z , ex} u + L ( {y}_{o} - {\hat{y}}_{o} ) , L = {( \begin{matrix}3 {ω}_{o} & 3 {ω}_{o}^{2} & {ω}_{o}^{3}\end{matrix} )}^{T} ∈ {R}^{3 \times 1} \qquad ( Equation 7 )$$

The value estimated by the extended state observer 220 is obtained from Equation 7 and a control input u that can stabilize the system can be designed with the following Equation 8:

$$u = \frac{1}{{b}_{0}} ( - {ω}_{c}^{2} ( {\hat{y}}_{o} - r ) - 2 {ξω}_{c} {\dot{\hat{y}}}_{o} - {\hat{d}}_{z} ) \qquad ( Equation 8 )$$

where there are total three gains (parameters) a user needs to gain-tune, that is, ωₒ, ω_{c}, and ξ, which may be adjusted through trial and error. ωₒ may be adjusted through trial and error when designing the observer gain matrix L. ω_{c} and ξ may be values for stabilizing the system to be controlled, that is, the heater 15 system. These may be the same in number as the gains (parameters) that need to be adjusted with a PID control method of a comparative embodiment.

Accordingly, compared to the PID control method of the comparative embodiment, the method for controlling temperature according to the present disclosure may not have an increased complexity of tuning. In addition, as described above, when designing the extended state observer 220, the order information of the system can be only used without using specific parameter values.

In addition, using a large observer gain, excellent command-following performance can be achieved if the control set reaches a steady-state. In addition, there is no transient response (overshoot) characteristic, and quick convergence to the target temperature is possible.

The extended state observer 220 may treat the state variables of the heater 15 system, and model uncertainty, nonlinearity, etc., of the system as the disturbance d_{z}.

The control unit 200 may input the state variables and the disturbances output from the extended state observer 220 to the compensation controller 230. The state variables may include a temperature T estimated by the extended state observer 220 and a differentiation T′ of the temperature. In addition, the disturbance d may include various values such as model uncertainty and nonlinearity estimated by the extended state observer 220.

The compensation controller 230 may perform feedback control based on the temperature T and the temperature differentiation T′ output from the extended state observer 220. The compensation controller 230 may perform a feedback control based on the target temperature r(t), the temperature T, and the differentiation T′ of the temperature. Specifically, the compensation controller 230 may calculate a first feedback compensation value based on the temperature T, calculate a second feedback compensation value based on the differentiation T′ of the temperature, and add them together.

In addition, the compensation controller 230 may perform a feedforward control based on the disturbance d output from the extended state observer 220. Specifically, the compensation controller 230 may calculate a feedforward compensation value based on the disturbance d and subtract the feedforward compensation value from the sum of the feedback compensation values.

The compensation controller 230 may generate a control input u(t) to transmit to the heater 15 based on the value calculated through the feedback and feedforward controls described above.

However, in the heater 15 system installed in the semiconductor processing apparatus, the time to reach the target temperature r(t) or the actual reaction rate of temperature in response to the control input u(t) may be slow. In other words, upon application of power to the heater 15, the actual temperature change may occur several seconds later. As such, the heater 15 system may be a system having a considerable time delay.

As described above, because the extended state observer 220 does not take into account the time delay of the system, more accurate state variables and disturbances can be estimated if data is additionally input in consideration of the time delay occurring in the heater 15 system. Hereinbelow, the control unit 200 that may input the temperature removed of the time delay to the extended state observer 220 will be described.

Referring to FIG. 5, in addition to the extended state observer 220 and the compensation controller 230, the control unit 200 may further include a time delay compensation unit 210 to remove time delay of the heater 15. The time delay compensation unit 210 may be a Smith predictor. However, the time delay compensation unit 210 is not limited thereto.

The time delay compensation unit 210 may calculate a first temperature T₁ removed of the time delay based on the measured temperature y(t) measured by the temperature sensor 16 and the control input u(t) of the control unit 200. The time delay compensation unit 210 may be implemented by using an approximate linear model for compensating the time delay of the heater 15 which is a system to be controlled.

The extended state observer 220 may estimate the state variable and disturbance of the heater 15 system based on the first temperature T₁ and the control input u(t) calculated from the time delay compensation unit 210. In this case, the state variable may include a second temperature T₂ estimated from the control input u(t) and the first temperature T₁, and a differentiation T₂′ of the second temperature. The disturbance dz may be treated as a lump disturbance by estimating uncertainty, nonlinearity, etc., of the heater 15 system.

With the removal of the time delay of the heater 15 system, the improved performance of the extended state observer 220 can be ensured. Therefore, using the time delay compensation unit 210, the first temperature T₁ removed of the time delay may be input to the extended state observer 220, thereby improving the temperature control performance of the heater 15 system.

The extended state observer 220 may estimate the second temperature T₂, the differentiation T₂′ of the second temperature, and the disturbance dz, based on the first temperature T₁ and the control input u(t). The estimated second temperature T₂, the differentiation T₂′ of the second temperature, and the disturbance dz may be input to the compensation controller 230.

The compensation controller 230 may perform a feedback control based on the second temperature T₂ and the differentiation T₂′ of the second temperature, and perform a feedforward control based on the disturbance dz.

Hereinbelow, each of the control modules of the control unit 200 will be described in detail.

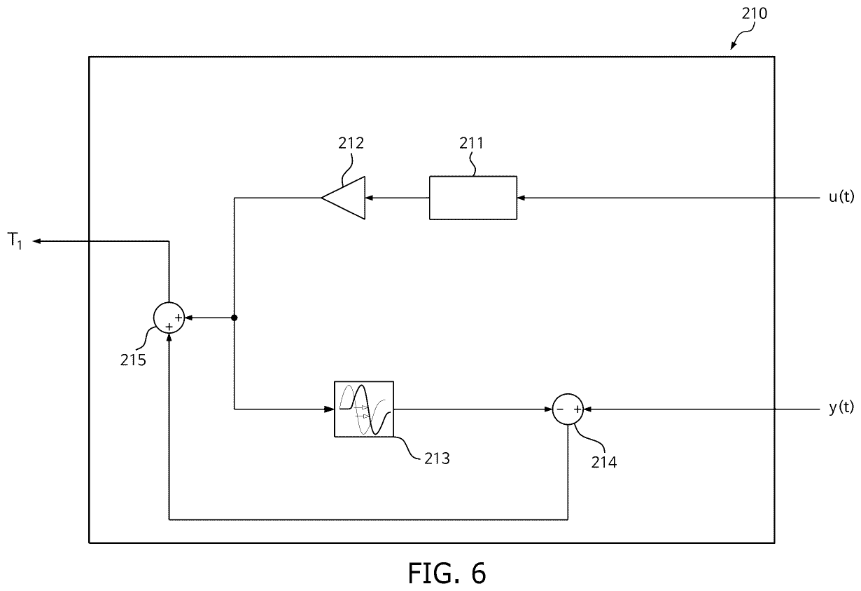

FIG. 6 is a block diagram illustrating a configuration of a Smith predictor of the control unit.

Referring to FIG. 6, a time delay compensation unit 210 (e.g., a Smith predictor) may receive a measured temperature y(t) and a control input u(t).

The time delay compensation unit 210 (e.g., the Smith predictor) may use (e.g., include) an approximate model 211 of the heater 15 system to remove the time delay. The approximate model 211 may be a linear model. The control input u(t) may be input to the approximate model 211, and the temperature output from the approximate model 211 may be multiplied by a proper gain 212. The temperature output from the approximate model 211 and multiplied by the gain 212 may be passed through a delay 213, and output as a temperature of the approximate model 211 with a time delay.

Meanwhile, in a subtractor 214, the temperature of the approximate model 211 with the time delay may be subtracted from the measured temperature y(t) of the actual system to obtain a difference thereof. The difference and the temperature of the approximate model 211 without the time delay may be added together by an adder 215, and the adder 215 may output a sum thereof. That is, the temperature output from the adder 215 may be the first temperature T₁ removed of the time delay.

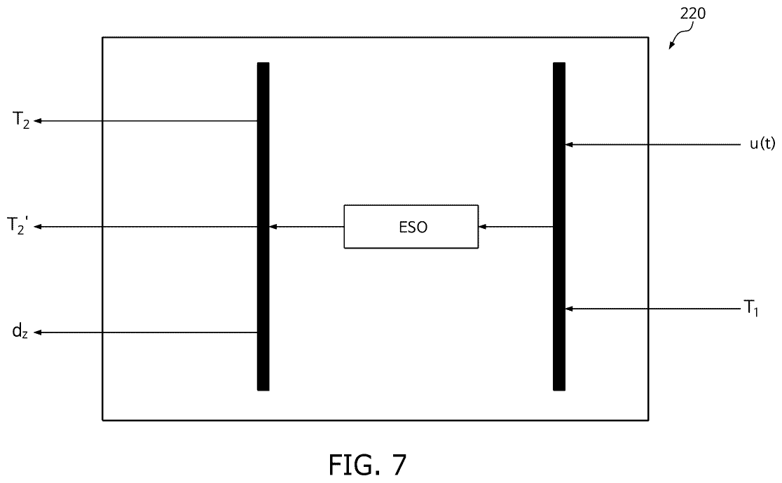

FIG. 7 is a block diagram illustrating a configuration of the extended state observer of the control unit.

Referring to FIG. 7, the extended state observer 220 may receive an input of the control input u(t) and the first temperature T₁ output from the time delay compensation unit 210 (e.g., the Smith predictor) and estimate the state variable and disturbance of the heater 15 system.

The state variable may include the second temperature T₂ estimated from the control input u(t) and the first temperature T₁, and the differentiation T₂′ of the second temperature T₂.

The disturbance dz may include uncertainty, nonlinearity, etc., of the system. In addition, the disturbance dz may indicate various disturbances including RF power disturbance, cooling disturbance, gas disturbance, etc. The cooling disturbance may be caused due to cooling by the cooler (e.g., the cooler 18, see FIG. 2) or cooling by helium (He) gas supplied from a rear surface of the wafer substrate W. The state variable and the disturbance dz estimated from the extended state observer 220 may be transmitted to the compensation controller 230.

The extended state observer 220 may estimate the disturbance dz in real time by treating a difference between the actual system and the approximate linear model as the disturbance dz. The estimated value of the disturbance dz may be used for feedforward control when designing the control input u(t).

The extended state observer 220 may not use a specific parameter value at all, and use only order information of the system. In addition, using a sufficiently large observer gain, excellent command-following performance can be achieved when the steady state is reached. In addition, there is no transient response (overshoot), and the time to converge to the target temperature r(t) can be reduced.

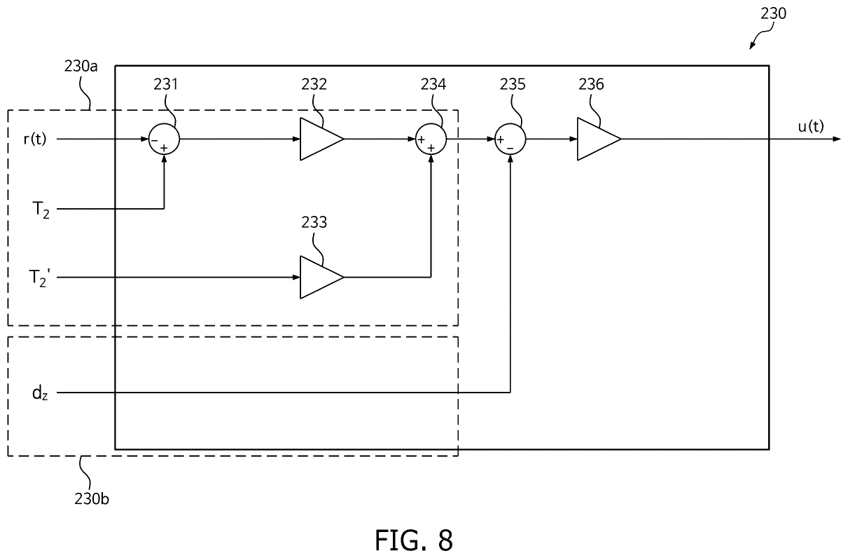

FIG. 8 is a block diagram illustrating a configuration of the compensation controller of the control unit.

Referring to FIG. 8, the compensation controller 230 may receive an input of the target temperature r(t), the second temperature T₂ estimated by extended state observer 220, and the differentiation T₂′ of the second temperature T₂.

The compensation controller 230 may include a feedback controller 230a that calculates a first feedback compensation value based on the target temperature r(t) and the second temperature T₂ estimated by the extended state observer 220 and a second feedback compensation value based on the differentiation T₂′ of the second temperature T₂.

The feedback controller 230a may include a subtractor 231 that subtracts the input temperature r(t) from the second temperature T₂ and outputs the result. The value output from the subtractor 231 may be multiplied by a first feedback gain 232 and output as a first feedback compensation value. The portion of the feedback controller 230a that obtains and outputs the first feedback compensation value may be referred to as a first feedback controller.

The feedback controller 230a may multiply the differentiation T₂′ of the second temperature T₂ by a second feedback gain 233 and output a second feedback compensation value. The portion of the feedback controller 230a that obtains and outputs the second feedback compensation value may be referred to as a second feedback controller.

The feedback controller 230a may further include an adder 234 that adds the first feedback compensation value and the second feedback compensation value together and outputs the result. The value output from the adder 234 may be transmitted to a subtractor 235 to be described later, and may be subtracted from the feedforward compensation value and output.

The compensation controller 230 may further include a feedforward controller 230b that calculates a feedforward compensation value based on the disturbance dz.

The feedforward controller 230b may calculate a feedforward compensation value based on the disturbance dz estimated from the extended state observer 220.

The compensation controller 230 may further include the subtractor 235 that subtracts the calculated feedforward compensation value from the feedback compensation value and outputs the result. In addition, the compensation controller 230 may calculate a control input u(t) by multiplying the value calculated from the subtractor 235 by a gain 236.

The calculated control input u(t) may be transmitted to the heater 15 so that the operation of the heater 15 can be controlled. Based on the control input uT, the heater 15 may change the temperature of the wafer substrate or the electro static chuck according to the target temperature r(t).

Hereinbelow, temperature change of the electro static chuck or the wafer substrate heated by the heater 15 according to the control input u(t) output as a result of inputting the target temperature r(t) to the control unit 200 including the configuration described above will be described.

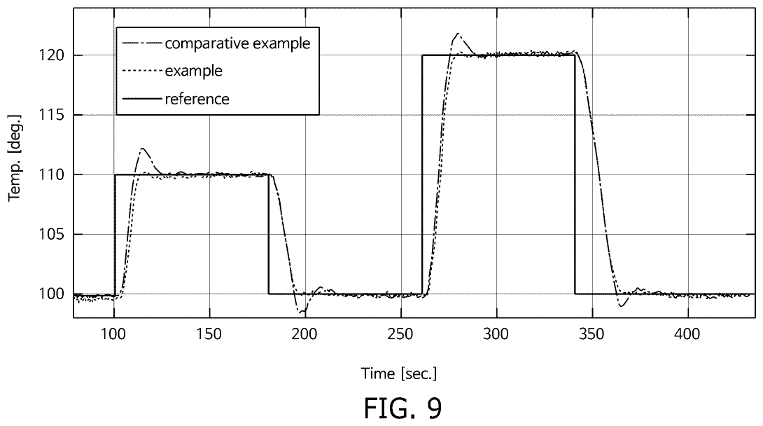

FIGS. 9 to 11 are graphs illustrating temperature change of the substrate processing apparatus according to some example embodiments of the present disclosure.

Referring to FIGS. 9 to 11, the temperature change according to the method for controlling temperature of the substrate processing apparatus 1 according to some example embodiments of the present disclosure will be described in comparison with a comparative example. In FIGS. 9 to 11, the result of temperature control of the comparative example shows the result of controlling the temperature of the heater 15 with the PID control method with appropriately adjusted gain values.

Referring to FIG. 9, the temperature change is shown, which is observed when the target temperature (reference) is set to 110° C. in a state in which the temperature of the electro static chuck or the wafer substrate is 100° C.

Referring first to the comparative example, it can be seen that the temperature exceeds 110° C. with the transient response (overshoot) occurring by about 2.2° C., and that it takes about 25 seconds to reach the target temperature of 110° C.

On the other hand, with the method for controlling temperature of the substrate processing apparatus according to some example embodiments of the present disclosure, it can be seen that there is almost no transient response (overshoot), which is about 0.3° C., and temperature converges to the target temperature of 110° C. at a rapid rate. That is, the time to converge to the target temperature is about 16 seconds, which is shorter than the time to converge of the comparative example.

In general, there is a kind of trade-off relationship in which the rate of convergence to the target temperature is delayed as the transient response (e.g., overshoot) occurs. That is, the larger the overshoot, the longer it takes to converge to the target temperature, resulting in a problem of decreasing rate of convergence to the target temperature. Conversely, controlling the temperature in order to increase the rate of convergence to the target temperature may result in greater overshoot. In this case, fine particles may be generated in the chamber of the substrate processing apparatus, and there may be a problem in the stability of the plasma in a comparative embodiment. The method for controlling temperature according to some example embodiments of the present disclosure may solve this problem because the rate of convergence to the target temperature becomes faster with little transient response.

For the semiconductor processing apparatus, the temperature of a wafer is a factor that greatly affects the yield and quality of the semiconductors, and precise temperature control for substrate support part such as the electro static chuck that directly affects the temperature of the wafer can be important. According to the method for controlling temperature of the substrate processing apparatus according to some example embodiments of the present disclosure, yield and quality of a semiconductor can be improved. In addition, it is possible to reduce the defect rate of the semiconductor and secure stability during the semiconductor process.

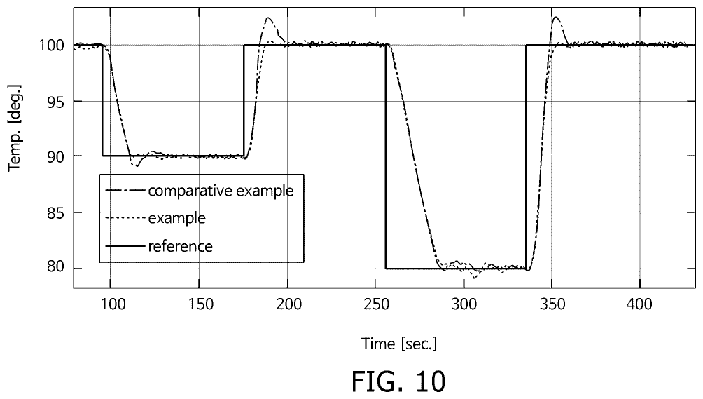

Referring again to FIG. 10 showing the temperature change that is observed when the target temperature (reference) is set to 100° C. in a state in which the temperature of the electro static chuck or the wafer substrate is 110° C., it may be seen that the transient response (undershoot) occurs in the comparative example, whereas the transient response hardly occurs with the method for controlling temperature according to some example embodiments of the present disclosure. In addition, compared to the comparative example, the time to converge to the target temperature of 100° C. is also shortened.

In addition, when the target temperature (reference) is set to 120° C. in a state in which the temperature of the electro static chuck or the wafer substrate is 100° C., the transient response (overshoot) occurs by about 1.8° C. in the comparative example, while there is almost no transient response, which is about 0.2° C., according to the example of the present disclosure.

As described above, it can be seen that the method for controlling temperature according to the example of the present disclosure has improved performance than the method of the comparative example when both increasing and decreasing the target temperature (reference). In addition, with the method for controlling temperature according to the example of the present disclosure, overshoot or undershoot rarely occurs, and the problem of the fine particles generated in the chamber of the substrate processing apparatus or the problem associated with the stability of plasma can also be reduced.

FIG. 10 illustrates a temperature change observed when the target temperature (reference) is set to 90° C. in a state in which the temperature of the electro static chuck or the wafer substrate is 100° C.

In the comparative example, the transient response (undershoot) occurs, while the transient response rarely occurs according to the examples of the present disclosure. Likewise, compared to the comparative example, the time to converge to the target temperature of 100° C. can also be shortened.

Meanwhile, when the target temperature (reference) is set to 100° C. in a state in which the temperature of the electro static chuck or the wafer substrate is 90° C., the comparative example showed a larger value of the transient response (overshoot) and longer convergence time than the example of the present disclosure. Therefore, it can be seen that even when the target temperature is increased or decreased by a larger gap, the example of the present disclosure exhibits improved performance compared to the comparative example.

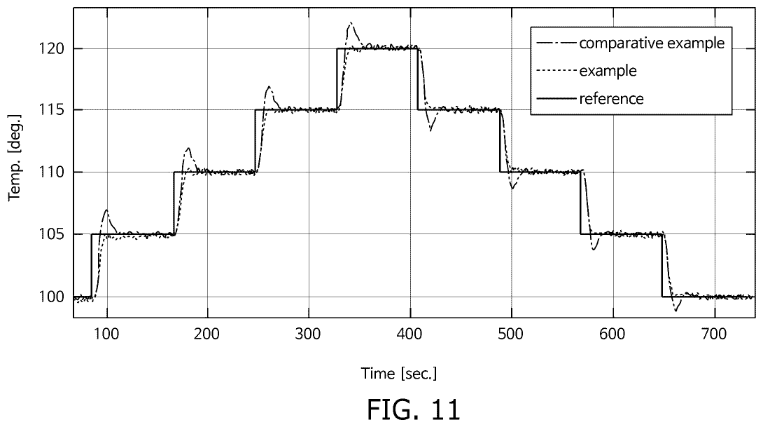

FIG. 11 illustrates a temperature change observed when the target temperature (reference) is set to 105° C. in a state in which the temperature of the electro static chuck or the wafer substrate is 100° C.

Referring to the comparative example, it can be seen that the temperature exceeds 105° C. with the transient response (overshoot) occurring by about 2.0° C., and that it also takes a long time to reach the target temperature of 105° C.

Meanwhile, it can be seen that the method for controlling temperature of the substrate processing apparatus 1 according to some example embodiments of the present disclosure converges to the target temperature of 110° C. with almost no transient response (overshoot), which is about 0.1° C.

The method for controlling temperature of the substrate processing apparatus according to some example embodiments of the present disclosure may exhibit excellent temperature control performance without using different models for various temperature change sections. That is, using the same model during both temperature increase and decrease, the method according to the example can still show an improved effect compared to the related PID control method applied to the comparative example.

In addition, the method for controlling temperature of the substrate processing apparatus according to some example embodiments of the present disclosure can provide improved temperature control performance with the same model even when the current temperature is not constant and the target temperature is raised or lowered at various temperatures.

Table 1 below compares numerically the degree of overshoot that occurs when the target temperature is raised above the current temperature with the method for controlling temperature according to the examples and the method according to the comparative example, respectively. The method for controlling temperature of the substrate processing apparatus according to the example of the present disclosure is significantly improved compared to the comparative example.

TABLE 1

| | Transient Response (Overshoot) | | |
|---|---|---|---|
| Temperature Change | Comparative | | Improvement |
| (° C.) | Example | Example | Rate (%) |
| 100 -> 105 | 2.0 | 0.1 | 95.0 |
| 100 -> 110 | 2.2 | 0.3 | 86.4 |
| 100 -> 120 | 1.8 | 0.2 | 88.9 |

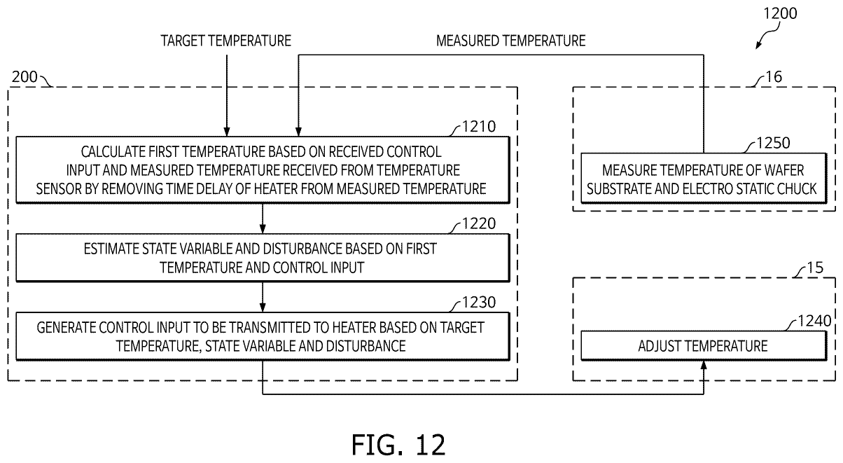

FIG. 12 is a flowchart provided to explain a method for controlling temperature of a substrate processing apparatus according to some example embodiments of the present disclosure.

The method 1200 for controlling temperature of the substrate processing apparatus according to some example embodiments of the present disclosure will be described with reference to the flowchart in FIG. 12. In describing the method 1200 for controlling temperature, the above description may be referenced for the description of the configuration and operation of the substrate processing apparatus and the temperature control system.

In the substrate processing apparatus, the temperature sensor 16 may measure the temperature of the electro static chuck 10 or the wafer substrate W, at operation S1250. In addition, the control unit 200 of the substrate processing apparatus may receive the target temperature. The control unit 200 may receive the measured temperature from the temperature sensor 16.

The method 1200 for controlling temperature may be initiated by the control unit 200 calculating the first temperature by removing the time delay of the heater 15 from the measured temperature based on the received control input and the measured temperature received from the temperature sensor 16, at operation S1210. The control unit 200 may calculate, using a Smith predictor, the first temperature based on the control input and the measured temperature, by removing the time delay of the heater from the measured temperature.

The control unit 200 may estimate the state variable and disturbance of the heater 15 or the heater 15 system based on the first temperature and the control input, at operation S1220. The control unit 200 may estimate, using the extended state observer, the state variable and disturbance of the heater 15 based on the first temperature and a control input.

The control unit 200 may generate the control input to be transmitted to the heater 15 based on the target temperature, the state variable, and the disturbance, at operation S1230. The control unit 200 may generate the control input by performing a feedback control based on the target temperature, the second temperature, and the differentiation of the second temperature. To this end, the control unit 200 may include the first feedback controller that calculates the first feedback compensation value based on the target temperature and the second temperature, the second feedback controller that calculates the second feedback compensation value based on the differentiation of the second temperature, and the feedforward controller that calculates the feedforward compensation value based on the disturbance.

The control unit 200 may transmit the generated control input to the heater 15. The heater 15 may adjust the temperature of the electro static chuck 10 or the wafer substrate W according to the control input received from the control unit 200, at operation S1240.

In addition, the control unit 200 may continuously receive the measured temperature detected by the temperature sensor 16 and repeatedly perform the method 1200 for controlling temperature including operation S1210 to operation S1240.

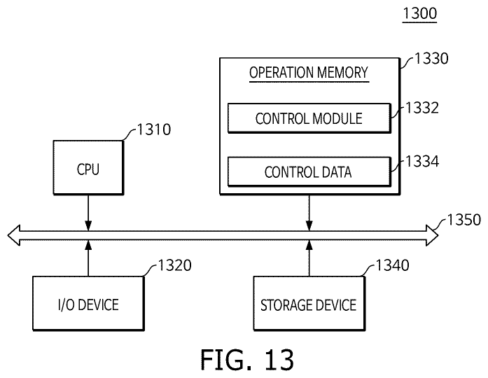

FIG. 13 is a block diagram illustrating a configuration of a computing device in which the control unit is implemented according to some example embodiments of the present disclosure.

FIG. 13 is a block diagram illustrating a computing device 1300 for implementing a control unit (e.g., the control unit 200, see FIG. 2) according to some example embodiments of the present disclosure. For example, the computing device 1300 may be an example of the control unit (e.g., the control unit 200, see FIG. 2). The computing device 1300 may include a CPU 1310, an operation memory 1330, an input/output (I/O) device 1320, and a storage device 1340.

The CPU 1310 may execute software (e.g., application programs including a program for performing the method for controlling temperature of the substrate processing apparatus, operating systems, device drivers) to be performed in the computing device 1300. The CPU 1310 may process data or output a control signal according to a program recorded in the operation memory 1330.

The operation memory 1330 may be a volatile memory such as a static random access memory (SRAM) or a dynamic random access memory (DRAM), or a nonvolatile memory such as phase-change random access memory (PRAM), magnetoresistive random access memory (MRAM), resistive random access memory (ReRAM), ferroelectric random access memory (FRAM), NOR flash memory, etc.

The operation memory 1330 may include control modules 1332 including a program code for performing the method for controlling temperature of the substrate processing apparatus, and control data 1334 including a measured temperature, a target temperature, parameters of an approximate model of the heater, etc., referred to by the control modules 1332.

According to some example embodiments of the present disclosure, the operation memory 1330 may include program code that is configured to, when executed by at least one processor (e.g., the CPU 1310), cause the control unit (e.g., the control unit 200, see FIG. 2) to perform its functions. For example, the program code may be configured to, when executed by at least one processor (e.g., the CPU 1310), implement a compensation controller (e.g., the compensation controller 230, see FIGS. 4-5 and 8), an extended state observer (e.g., the extended state observer 220, see FIGS. 4-5 and 7), and/or a time delay compensation unit (e.g., the time delay compensation unit 210, see FIGS. 5-6).

The input/output (I/O) device 1320 controls user input and output to and from a user interface. For example, it may include an input interface for the user to set the target temperature and an output interface to output data such as the temperature of the wafer substrate, etc.

The storage device 1340 is provided as storage medium of the computing device 1300. The storage device 1340 may store various data such as temperature change data of the wafer substrate, etc. The storage device 1340 may be provided as a memory card (MultiMediaCard (MMC), embedded MultiMediaCard (eMMC), Secure Digital (SD), MicroSD, etc.) or a hard disk drive (HDD). The storage device 1340 may include a NAND-type flash memory having a large storage capability. Alternatively, the storage device 1340 may include a next-generation nonvolatile memory such as PRAM, MRAM, ReRAM, FRAM, or a NOR flash memory.

Certain non-liming example embodiments of the present disclosure have been described above for purposes of illustration only, and those skilled in the art with ordinary knowledge of the present disclosure will be able to make various modifications, changes, and additions that are included within the spirit and scope of the present disclosure.

What is claimed is:

1. A substrate processing apparatus, comprising:
a heater configured to adjust a temperature of a periphery of a wafer substrate;
a temperature sensor configured to measure the temperature of the periphery of the wafer substrate; and
a controller configured to generate a control input based on a target temperature and based on a measured temperature obtained from the temperature sensor, and transmit the control input to the heater,
wherein the controller is further configured to:
calculate a first temperature based on the control input and the measured temperature by removing a time delay of the heater from the measured temperature;
estimate a state variable and a disturbance of the heater based on the first temperature and the control input; and
generate the control input to be transmitted to the heater based on the target temperature, the state variable, and the disturbance.

2. The substrate processing apparatus of claim 1, wherein the state variable comprises a second temperature estimated by the controller from the control input and the first temperature, and a differentiation of the second temperature.

3. The substrate processing apparatus of claim 2, wherein the controller is further configured to generate the control input by performing a feedback control based on the target temperature, the second temperature, and the differentiation of the second temperature.

4. The substrate processing apparatus of claim 3, wherein the controller comprises a first feedback controller configured to calculate a first feedback compensation value based on the target temperature and the second temperature.

5. The substrate processing apparatus of claim 4, wherein the controller further comprises a second feedback controller configured to calculate a second feedback compensation value based on the differentiation of the second temperature.

6. The substrate processing apparatus of claim 5, wherein the controller further comprises a feedforward controller configured to calculate a feedforward compensation value based on the disturbance.

7. The substrate processing apparatus of claim 6, wherein the controller is further configured to generate the control input based on the first feedback compensation value, the second feedback compensation value, and the feedforward compensation value.

8. The substrate processing apparatus of claim 1, wherein the controller comprises a Smith predictor that is configured to calculate the first temperature based on the control input and the measured temperature, by removing the time delay of the heater from the measured temperature.

9. The substrate processing apparatus of claim 1, wherein the controller comprises an extended state observer (ESO) that is configured to estimate the state variable and the disturbance of the heater based on the first temperature and the control input.

10. The substrate processing apparatus of claim 1, wherein the temperature sensor is under the wafer substrate.

11. A substrate processing apparatus, comprising:
an electro static chuck configured to support a wafer substrate;
a heater configured to heat at least one from among the electro static chuck and the wafer substrate;
a temperature sensor configured to measure a temperature of the wafer substrate; and
a controller configured to generate a control input based on a target temperature and based on a measured temperature obtained from the temperature sensor, and transmit the control input to the heater,
wherein the controller comprises:
a Smith predictor configured to calculate a first temperature based on the control input and the measured temperature by removing a time delay of the heater from the measured temperature;
an extended state observer configured to estimate, based on the first temperature and the control input, a second temperature of the heater, a differentiation of the second temperature, and a disturbance; and
a compensation controller configured to generate the control input to be transmitted to the heater based on the target temperature, the second temperature, the differentiation of the second temperature, and the disturbance.

12. The substrate processing apparatus of claim 11, wherein the compensation controller is further configured to generate the control input by performing a feedback control based on the target temperature, the second temperature, and the differentiation of the second temperature.

13. The substrate processing apparatus of claim 12, wherein the compensation controller comprises a first feedback controller configured to calculate a first feedback compensation value based on the target temperature and the second temperature.

14. The substrate processing apparatus of claim 13, wherein the compensation controller further comprises:
a second feedback controller configured to calculate a second feedback compensation value based on the differentiation of the second temperature; and
an adder configured to obtain a feedback compensation value by adding together the first feedback compensation value and the second feedback compensation value, and output the feedback compensation value.

15. The substrate processing apparatus of claim 14, wherein the compensation controller further comprises:
a feedforward controller configured to calculate a feedforward compensation value based on the disturbance; and
a subtractor configured to obtain a value by subtracting the feedback compensation value, calculated by the adder, from the feedforward compensation value, and output the value.

16. The substrate processing apparatus of claim 15, wherein the compensation controller is further configured to generate the control input to be transmitted to the heater based on the value output from the subtractor.

17. The substrate processing apparatus of claim 11, further comprising a cooler configured to cool the electro static chuck,
wherein the disturbance comprises a cooling disturbance indicating an effect of the cooler on the heater.

18. A substrate processing apparatus, comprising:
an electro static chuck configured to support a wafer substrate;
a heater configured to heat at least one from among the electro static chuck and the wafer substrate;
a temperature sensor configured to measure a temperature of the wafer substrate, wherein the temperature sensor is under the wafer substrate; and
a controller configured to generate a control input based on a target temperature and based on a measured temperature obtained from the temperature sensor, and transmit the control input to the heater,
wherein the controller comprises:
a Smith predictor configured to calculate a first temperature based on the control input and the measured temperature by removing a time delay of the heater from the measured temperature;
an extended state observer configured to estimate, based on the first temperature and the control input, a second temperature of the heater, a differentiation of the second temperature, and a disturbance;
a feedback controller configured to calculate a feedback compensation value based on the target temperature, the second temperature, and the differentiation of the second temperature; and
a feedforward controller configured to calculate a feedforward compensation value based on the disturbance.

19. The substrate processing apparatus of claim 18, wherein the feedback controller comprises:
a first feedback controller configured to calculate a first feedback compensation value based on the target temperature and the second temperature;
a second feedback controller configured to calculate a second feedback compensation value based on the differentiation of the second temperature; and
an adder configured to obtain the feedback compensation value by adding together the first feedback compensation value and the second feedback compensation value, and output the feedback compensation value.

20. The substrate processing apparatus of claim 19, wherein the controller further comprises a subtractor configured to obtain a value by subtracting the feedback compensation value, calculated by the adder, from the feedforward compensation value, and output the value, and
wherein the control unit is further configured to generate the control input to be transmitted to the heater based on the value output from the subtractor.
